(19) United States
(12) Patent Application Publication
(10) Pub. No.: US 2026/0280584 A1
(43) Pub. Date: Sep. 17, 2026

(54) HAPTIC SIGNAL INTERPOLATION

(71) Applicant: Tencent Technology (Shenzhen) Company Limited, Shenzhen (CN)

(72) Inventors: Ying HU, Shenzhen (CN); Xiaozhong XU, Shenzhen (CN)

(73) Assignee: Tencent Technology (Shenzhen) Company Limited, Shenzhen (CN)

(21) Appl. No.: 19/670,878

(22) Filed: May 7, 2026

Related U.S. Application Data
(63) Continuation of application No. PCT/CN2024/109314, filed on Aug. 1, 2024.

(30) Foreign Application Priority Data
Dec. 11, 2023 (CN) 202311693600.6

(51) Int. Cl. H03M 7/30; H04B 5/20

(52) U.S. Cl. CPC H03M 7/6011; H03M 7/70; H04B 5/20

(57) ABSTRACT

Some aspects of the disclosure provide a method of haptic signal interpolation. In some examples, a bit stream including coded information of a haptic signal is received. The haptic signal includes a plurality of haptic events. An interpolation type of a first haptic event component in a first haptic event is determined according to at least an identifier in the coded information of the haptic signal. A signal value interpolation between a first signal value of the first haptic event component and a second signal value of a second haptic event component is performed based on the interpolation type of the first haptic event component, the second haptic event component precedes or follows the first haptic event component. The haptic signal is reconstructed based on at least the signal value interpolation. Apparatus and non-transitory computer-readable storage medium counterpart embodiments are also contemplated.

### RELATED APPLICATIONS

The present application is a continuation of International Application No. PCT/CN2024/109314, filed on Aug. 1, 2024, which claims priority to Chinese Patent Application No. 202311693600.6, filed on Dec. 11, 2023. The entire disclosures of the prior applications are hereby incorporated by reference.

### FIELD OF THE TECHNOLOGY

This disclosure relates to the technical field of haptic signal encoding and decoding, including techniques of haptic signal interpolation.

### BACKGROUND OF THE DISCLOSURE

Presentation of immersive media content is usually accompanied by various wearable devices or interactive devices. Therefore, regarding a presentation mode of immersive media, in addition to conventional visual and auditory presentation, immersive media further features a new presentation mode of haptic presentation. Haptic presentation uses a haptic presentation mechanism combining hardware and software to allow users to receive information though their bodies, to provide an embedded physical sensation, thereby conveying key information of a system being used by the users. For example, a mobile phone can alert a user to received information through vibration, and such vibration is a type of haptic presentation. Haptic presentation can enhance auditory and visual presentation, thereby improving user experience.

In related technologies, haptic presentation can be implemented through transmission of a haptic signal. In some examples, the haptic signal may be defined as a haptic event, and support is provided for decomposing the haptic event into a plurality of haptic event components, thereby implementing transmission of the haptic signal.

However, the method of defining the haptic signal may cause excessively poor flexibility of haptic signal representation and excessively large overhead for representation, resulting in problems such as excessively poor user experience of haptic media consumers and excessively large bandwidth consumption of haptic media transmission.

### SUMMARY

Embodiments of this disclosure provide a haptic signal interpolation method and apparatus, an electronic device, and a storage medium, which can represent different types of haptic signals more accurately and flexibly, and save on overhead for haptic signal representation, thereby improving user experience of haptic media consumers and reducing bandwidth consumption of haptic media transmission.

Some aspects of the disclosure provide a method of haptic signal interpolation. In some examples, a bit stream including coded information of a haptic signal is received. The haptic signal includes a plurality of haptic events. An interpolation type of a first haptic event component in a first haptic event is determined according to at least an identifier in the coded information of the haptic signal. A signal value interpolation between a first signal value of the first haptic event component and a second signal value of a second haptic event component is performed based on the interpolation type of the first haptic event component, the second haptic event component precedes or follows the first haptic event component. The haptic signal is reconstructed based on at least the signal value interpolation.

Some aspects of the disclosure provide a method of haptic signal interpolation. For example, a haptic signal is acquired. A first interpolation type is determined based on the haptic signal. The haptic signal is encoded into coded information in a bit stream of the haptic signal based on the first interpolation type. The first interpolation type is encoded based on at least an identifier in the coded information, and is used for performing a signal value interpolation between a first signal value of a first haptic event component and a second signal value of a second haptic event component in a first haptic event, and the second haptic event component precedes or follows the first haptic event component.

According to a first aspect, an embodiment of this disclosure provides a haptic signal interpolation method, applied to a decapsulation device or a signal processing device, and the method including: determining an interpolation type of a first haptic event component in a first haptic event by decoding a bit stream of a haptic signal; and performing signal value interpolation between a signal value of the first haptic event component and a signal value of a second haptic event component based on the interpolation type of the first haptic event component, to obtain the haptic signal, the second haptic event component being a haptic event component preceding or following the first haptic event component.

According to a second aspect, an embodiment of this disclosure provides a haptic signal interpolation method, applied to an encapsulation device or a signal processing device, where the method includes: acquiring a haptic signal; and determining a first interpolation type based on the haptic signal, the first interpolation type being configured for performing signal value interpolation between a signal value of a first haptic event component and a signal value of a second haptic event component in a first haptic event, and the second haptic event component being a haptic event component preceding or following the first haptic event component.

According to a third aspect, an embodiment of this disclosure provides a haptic signal interpolation apparatus, applied to a decapsulation device or a signal processing device, where the apparatus includes: a determining unit, configured to determine an interpolation type of a first haptic event component in a first haptic event by decoding a bit stream of a haptic signal; and an interpolation unit, configured to perform signal value interpolation between a signal value of the first haptic event component and a signal value of a second haptic event component based on the interpolation type of the first haptic event component, to obtain the haptic signal, the second haptic event component being a haptic event component preceding or following the first haptic event component.

According to a fourth aspect, an embodiment of this disclosure provides a haptic signal interpolation apparatus, applied to an encapsulation device or a signal processing device, where the apparatus includes: an acquiring unit, configured to acquire a haptic signal; and a determining unit, configured to determine a first interpolation type based on the haptic signal, the first interpolation type being configured for performing signal value interpolation between a signal value of a first haptic event component and a signal value of a second haptic event component in a first haptic event, and the second haptic event component being a haptic event component preceding or following the first haptic event component.

According to a fifth aspect, an embodiment of this disclosure provides an electronic device, including: a processor, suitable for implementing computer instructions; and a computer-readable storage medium, the computer-readable storage medium having the computer instructions stored therein, and the computer instructions being suitable for being loaded by the processor to execute the method provided in the first aspect or the second aspect involved above.

According to a sixth aspect, this disclosure provides a chip, configured to implement the method provided in the first aspect or the second aspect. In some examples, the chip includes: a processor (an example of processing circuitry), configured to call and run a computer program from a memory, so that a device equipped with the chip executes the method provided in the first aspect or the second aspect.

According to a seventh aspect, an embodiment of this disclosure provides a computer-readable storage medium (e.g., non-transitory computer-readable storage medium), the computer-readable storage medium having computer instructions stored therein, and the computer instructions, when read and executed by a processor of a computer device, causing the computer device to execute the method provided in the first aspect or the second aspect involved above.

According to an eighth aspect, an embodiment of this disclosure provides a computer program product or a computer program, the computer program product or the computer program including computer instructions, and the computer instructions being stored in a computer-readable storage medium. A processor of a computer device reads the computer instructions from the computer-readable storage medium, and the processor executes the computer instructions, so that the computer device executes the method provided in the first aspect or the second aspect involved above.

In the embodiments of this disclosure, the decapsulation device determines the interpolation type of the first haptic event component in the first haptic event by decoding the bit stream of the haptic signal; and signal value interpolation is performed between the signal value of the first haptic event component and the signal value of the second haptic event component based on the interpolation type of the first haptic event component, to obtain the haptic signal, the second haptic event component being the haptic event component preceding or following the first haptic event component. Equivalently, through signal value interpolation, the decapsulation device not only can flexibly restore different types of haptic signals, that is, represent different types of haptic signals more accurately and flexibly, but also can reduce information about haptic event components that needs to be carried in the bit stream, that is, can save on overhead for haptic signal representation, thereby improving user experience of haptic media consumers and reducing bandwidth consumption of haptic media transmission.

### BRIEF DESCRIPTION OF THE DRAWINGS

FIG. 1 is a schematic diagram of three degrees of freedom according to an embodiment of this disclosure.

FIG. 2 is a schematic diagram of three degrees of freedom plus according to an embodiment of this disclosure.

FIG. 3 is a schematic diagram of six degrees of freedom according to an embodiment of this disclosure.

FIG. 4 is a schematic diagram of a system architecture according to an embodiment of this disclosure.

FIG. 5 is a schematic diagram of an immersive media system according to an embodiment of this disclosure.

FIG. 6 is a schematic diagram of a data structure of haptic information representation according to an embodiment of this disclosure.

FIG. 7 is a schematic flowchart of a haptic signal interpolation method according to an embodiment of this disclosure.

FIG. 8 is an example of a format of a bit stream according to an embodiment of this disclosure.

FIG. 9 is an example of an interpolation principle according to an embodiment of this disclosure.

FIG. 10 is a schematic flowchart of another haptic signal interpolation method according to an embodiment of this disclosure.

FIG. 11 is a schematic block diagram of a haptic signal interpolation apparatus according to an embodiment of this disclosure.

FIG. 12 is a schematic block diagram of another haptic signal interpolation apparatus according to an embodiment of this disclosure.

FIG. 13 is a schematic block diagram of an electronic device according to an embodiment of this disclosure.

### DESCRIPTION OF EMBODIMENTS

The following describes technical solutions in embodiments of this disclosure with reference to the accompanying drawings. The described embodiments are some of the embodiments of this disclosure rather than all of the embodiments. Other embodiments are within the scope of this disclosure.

Examples of terms involved in the aspects of the disclosure are briefly introduced. The descriptions of the terms are provided as examples only and are not intended to limit the scope of the disclosure.

Haptics: Haptics can refer to a sensory experience, such as vibration, pressure, and temperature, obtained by a human body through contact.

Haptic signal: A haptic signal can refer to a signal configured for representing haptic experience in a specific modality, and is rendered and presented on a specific device.

JavaScript Object Notation (JSON): JSON can refer to a lightweight data interchange format. JSON uses a text format completely independent of a programming language to store and represent data. A simple and clear hierarchical structure makes JSON an ideal data exchange language, which is easy for humans to read and write, facilitates machine parsing and generation, and effectively improves network transmission efficiency.

Bit stream: A bit stream is also referred to as a bitstream, and can refer to a compressed and encoded binary data stream.

Track: A track can refer to a media data set in a media file encapsulation process, and can include a plurality of sequential samples. One media file may include one or more tracks. For example, one media file may include one video media track, one audio media track, and one subtitle media track. In some examples, metadata information may also be used as a media type, and is included in the file in a form of a metadata media track.

Item: An item can refer to an encapsulation unit of non-sequential media data in the media file encapsulation process. For example, one static picture may be encapsulated as one item.

Sample: A sample can refer to an encapsulation unit in the media file encapsulation process, one track is formed by a plurality of samples, and each sample corresponds to specific timestamp information. For example, one video media track may be formed by a plurality of samples, and one sample is usually one video frame. In the embodiments of this disclosure, one sample in a haptic media track may be one or more haptic signals.

Sub-sample: A sub-sample can refer to a part of sample data.

Sample number: A sample number can refer to a sequence number of a sample. For example, a sequence number of the first sample in the track is 1.

Sample entry: A sample entry can indicate all sample-related metadata information in the track. For example, a sample entry of a video track usually includes metadata information related to decoder initialization.

Sample group: A sample group is configured to group some samples in the track according to a specific rule.

Dynamic adaptive streaming over HTTP (DASH): DASH is an adaptive bitrate streaming technology, enabling high-quality streaming media to be transmitted on the Internet through a conventional HTTP network server.

Media presentation description (MPD): MPD can refer to a media presentation description signaling in the DASH, and is configured for describing media segment information.

Representation: A representation can refer to a combination of one or more media components in the DASH. For example, a video file of a certain resolution may be considered as one representation.

Adaptation sets: An adaptation set can refer to a set of one or more video streams in the DASH, and one adaptation set may include a plurality of representations.

Media segment: A media segment can refer to a playable segment conforming to a specific media format. During playback, the media segment may need to coordinate with zero or a plurality of preceding segments and an initialization segment.

Degree of freedom (DoF): A DoF can refer to a degree of freedom in which movement is supported and content interaction is generated when a user watches immersive media.

Three degrees of freedom (3DoF): For example, as shown in FIG. 2, 3DoF can refer to three degrees of freedom that allows the user to rotate the head around an x-axis, a y-axis, and a z-axis.

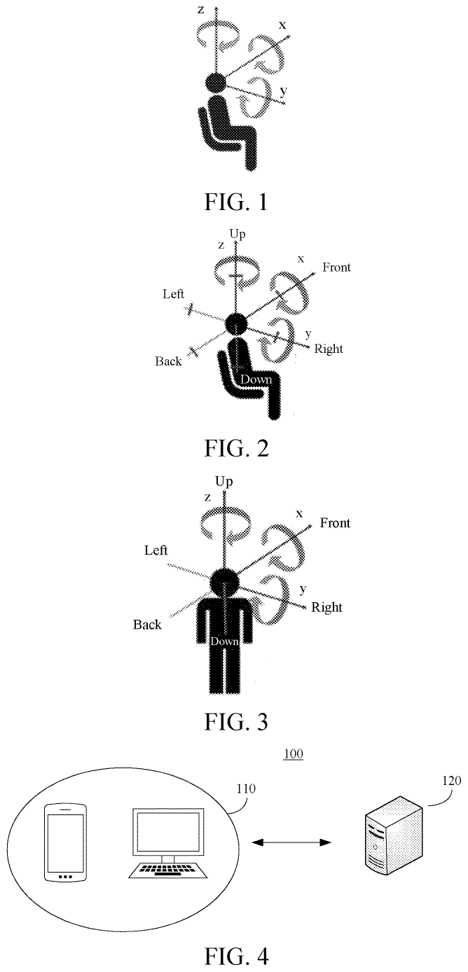

Three degrees of freedom plus (3DoF+): Based on three degrees of freedom, limited degree(s) of freedom can be used to make limited movement along the x-axis, the y-axis, and the z-axis. For example, as shown in FIG. 3, based on three degrees of freedom, limited degree of freedom can be used to move forward and backward, left and right along the x-axis, the y-axis, and the z-axis.

Six degrees of freedom (6DoF): Based on three degrees of freedom, additional degree(s) of freedom can be used to move along the x-axis, the y-axis, and the z-axis. For example, as shown in FIG. 4, based on three degrees of freedom, additional degrees of freedom are used to move forward and backward, left and right along the x-axis, the y-axis, and the z-axis.

Audio video coding standard (AVS): AVS can refer to a technical specification for compressing and encoding audio and video data, and aim to reduce storage space and transmission bandwidth of audio and video data, while maintaining high audio and video quality.

ISO based media file format (ISOBMFF): ISOBMFF can refer to an encapsulation standard of the media file, such as an MP4 file.

Smart media transport (SMT) standard: SMT can refer to a smart media transport technology encompassing an encapsulation format, a transport protocol, and a signaling message, to be applied to transmission and delivery of multimedia data under a heterogeneous packet switching network.

Media asset (asset): A media asset can refer to any multimedia data entity related to a unique identifier and configured for constructing a multimedia presentation.

The terms used in the implementations of this disclosure are merely used for explaining the embodiments of this disclosure, but are not intended to limit this disclosure.

For example, the term “and/or” in this specification describes only an association relationship between associated objects and represents that three relationships may exist. For example, A and/or B may represent the following three cases: Only A exists, both A and B exist, and only B exists. The term “at least one” describes only a combination relationship between listed objects and represents that one or more may exist. For example, at least one of the following: A, B, and C may represent the following combination cases: Only A exists, only B exists, only C exists, both A and B exist, both A and C exist, both B and C exist, and both A, B, and C exist. The term “plurality of” refers to two or more. The character “/” generally represents an “or” relationship between the associated objects.

For another example, the term “correspond to” may represent a direct correspondence or an indirect correspondence between the two, may represent an association relationship between the two, or may represent an indication relationship, a configuration relationship, or the like. The term “indicate” may be a direct indication, an indirect indication, or an indication of an association relationship. For example, A indicates B, which may represent that A directly indicates B, for example, B can be acquired through A; or may represent that A indirectly indicates B, for example, A indicates C, and B can be acquired through C. Alternatively, it may indicate that A and B have an association relationship. The term “predefine” or “preconfigure” may refer to the corresponding code, table, or other related information for indication that can be prestored in the device, or that is agreed on by a protocol. The “protocol” may refer to a standard protocol in the field. The term “when . . . ” may be explained as “if”, “in case of”, “while . . . ”, “in response to”, or the like. Similarly, depending on the context, phrases “if determining” or “if detecting (a stated condition or event)” may be explained as “when determining”, “in response to determining”, “when detecting (the stated condition or event)”, “in response to detecting (the stated condition or event)”, or the like. The terms “first”, “second”, “third”, “fourth”, “A^{th}”, “B^{th}”, and the like are intended to distinguish between different objects and are not used to describe a specific sequence. The terms “include”, “have”, and any variant thereof are intended to cover a non-exclusive inclusion. A digital video compression technology is mainly to compress massive digital image and video data, to facilitate transmission, storage, and the like.

The following describes application scenarios, technical problems to be resolved, and concepts of the embodiments of this disclosure.

Solutions provided in this disclosure may further relate to the field of vehicle technologies.

The solutions provided in this disclosure may further relate to encoding and decoding standards or technologies.

The solutions provided in this disclosure can be applied to the field of digital video encoding technologies, for example, the field of image encoding and decoding, the field of video encoding and decoding, the field of hardware video encoding and decoding, the field of dedicated circuit video encoding and decoding, and the field of real-time video encoding and decoding. Alternatively, the solutions provided in this disclosure can be combined with: an audio video coding standard (AVS), a second-generation AVS standard (AVS2), or a third-generation AVS standard (AVS3), including, but not limited to, an H.264/audio video coding (AVC) standard, an H.265/high efficiency video coding (HEVC) standard, and an H.266/versatile video coding (VVC) standard. Alternatively, the solutions provided in this disclosure can be combined with other exclusive or industry standards, for example, including ITU-TH.261, ISO/IECMPEG-1 Visual, ITU-TH.262 or ISO/IECMPEG-2 Visual, ITU-TH.263, ISO/IECMPEG-4 Visual, and ITU-TH.264 (which may also be referred to as ISO/IECMPEG-4 AVC), and also including scalable video coding (SVC) and multi-view video coding (MVC) extensions.

A client involved in this disclosure may be a user terminal. In one embodiment, the user terminal includes, but is not limited to, a mobile phone, a computer, an intelligent voice interaction device, an intelligent household appliance, an in-vehicle terminal, a flight vehicle, and the like.

FIG. 4 is a schematic diagram of an application scenario 100 applicable to an embodiment of this disclosure.

As shown in FIG. 4, the application scenario 100 may include a terminal 110 and a server 120. The terminal 110 is directly or indirectly connected to the server 120 in a wired or wireless manner.

The server 120 may manufacture or collect a haptic media signal based on an expected haptic effect, and generate an interchange format of the haptic signal. The interchange format of the haptic signal may also be referred to as signal data conforming to the interchange format. After generating the interchange format of the haptic signal, the server 120 may encode the interchange format of the haptic signal to obtain a bit stream (which may also be referred to as a bitstream) of the haptic signal, encapsulate the bit stream of the haptic signal to obtain a media file or a media segment of the haptic signal, and then transmit the media file or the media segment to a client 110.

Correspondingly, after receiving the media file or the media segment transmitted by the server 120, the terminal 110 can first decapsulate and decode the media file or the media segment to obtain the interchange format of the haptic signal, and render and present the signal based on the interchange format of the haptic signal. The terminal 110 may be any electronic product that can perform human-computer interaction with a user through one or more manners such as a keyboard, a touchpad, a touchscreen, a remote control, voice, or handwriting.

For example, the terminal may include, but is not limited to, a terminal side device such as the mobile phone, a tablet personal computer, a laptop computer, a notebook computer, a personal digital assistant (PDA), a palmtop computer, a netbook, an ultra-mobile personal computer (UMPC), a mobile internet device (MID), an augmented reality (AR), a virtual reality (VR) device, a robot, a wearable device, a flight vehicle, a vehicle user equipment (VUE), a shipborne equipment, a pedestrian user equipment (PUE), a smart appliance (a household device having a wireless communication function, such as a refrigerator, a television, a washing machine, or furniture), a game console, a personal computer (PC), an automated teller machine, or a self-service machine. The wearable device includes: a smart watch, a smart bracelet, a smart earphone, smart glasses, smart jewelry (a smart bangle, a smart chain bracelet, a smart ring, a smart necklace, a smart anklet, a smart ankle chain, and the like), a smart wristband, smart clothing, and the like. The vehicle user equipment may also be referred to as an in-vehicle terminal, an in-vehicle controller, an in-vehicle module, an in-vehicle component, an in-vehicle chip, an in-vehicle unit, or the like.

The server 120 may be an independent physical server, or may be a server cluster or a distributed system including a plurality of physical servers, or may be a cloud server providing a basic “cloud” computing service such as a cloud service, a cloud database, cloud computing, a cloud function, cloud storage, a network service, cloud communication, a middleware service, a domain name service, a security service, a content delivery network (CDN), or a big data and artificial intelligence platform.

The terminal 110 and the server 120 are merely examples. Other existing or future implementations of other terminals or servers that may be applicable to this disclosure also fall within the protection scope of this disclosure, which is incorporated herein by reference.

Solutions provided in this disclosure relate to immersive media content, and related content of the immersive media content is described below.

The immersive media content refers to media content that can bring immersive experience to a consumer. The immersive media content may be classified into 3DoF media, 3DoF+ media, and 6DoF media according to a degree of freedom during media content consumption of a user.

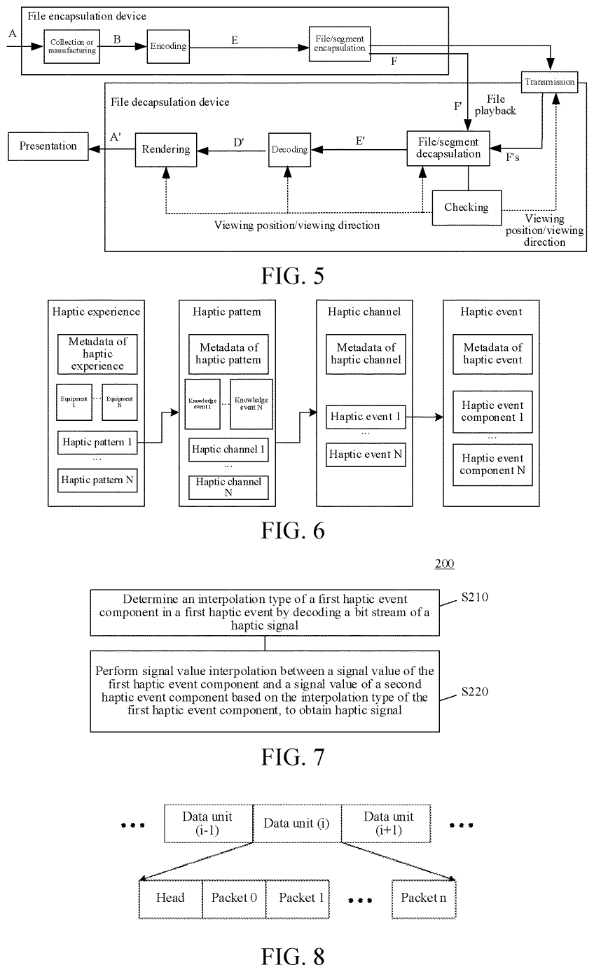

FIG. 5 is a schematic diagram of an immersive media system according to an embodiment of this disclosure.

As shown in FIG. 5, the immersive media system includes a file encapsulator and a file decapsulator.

An expected haptic media effect (A) may be configured to collect or manufacture an interchange format (B) of a haptic signal, and the interchange format of the haptic signal may also be referred to as signal data conforming to the interchange format. The interchange format (B) is encoded to obtain a bit stream (E). Then, based on a specific file format, the bit stream (E) is assembled into a media file (F) for file playback or a sequence of an initialization segment and a media segment for streaming transmission (Fs). The file encapsulator may further include metadata into a file or a segment. The segment Fs is delivered to a player through a delivery mechanism.

A file (F) outputted by the file encapsulator is the same as a file (F′) inputted to the file decapsulator. The file decapsulator processes a media file (F′) or a received segment (F′s), obtains a bit stream (E′) through decapsulation, and obtains an interchange format (D′) through parsing. The interchange format (D′) may be configured for rendering and presentation to a user. In an applicable case, a visual image is rendered and dynamically displayed on a screen of a head-mounted display or any other display device based on a current viewing position, viewing direction, or a viewport determined by various types of sensors (such as a head sensor). Dynamic display can be implemented by using a position sensor or an eye-tracking sensor.

Presentation of immersive media content is usually accompanied by various wearable devices or interactive devices. Therefore, regarding a presentation mode of immersive media, in addition to conventional visual and auditory presentation, immersive media further features a new presentation mode of haptic presentation. Haptic presentation uses a haptic presentation mechanism combining hardware and software to allow users to receive information though their bodies, to provide an embedded physical sensation, thereby conveying key information of a system being used by the users. For example, a mobile phone can alert a user to received information through vibration, and such vibration is a type of haptic presentation. Haptic presentation can enhance auditory and visual presentation, thereby improving user experience.

Currently, haptic information presentation has been widely applied, and is usually classified into the following categories: vibration haptics, which directly performs haptic presentation in a form of vibration; kinematic haptics, which simulates a movement state such as weight or pressure of an object; and electro haptics, which uses electrical stimulation to simulate feedback information about a specific texture. Details are provided as follows:

### 1. Vibration Haptics

Vibration of a specific frequency and intensity is simulated through motor vibration of a terminal device. For example, in a shooting game, a specific effect of a device during use is simulated through vibration.

### 2. Kinematic Haptics

A kinematic haptic system simulates a weight or pressure of an object. For example, in a driving video game, when moving at a high speed or operating a heavy vehicle, a steering wheel may resist rotation. This type of feedback directly affects muscles of the user. In an example of the driving game, the user needs to exert more force to obtain a required response from the steering wheel.

### 3. Electro Haptics

Electro haptic presentation uses electrical pulses to provide haptic stimulation to nerve endings on user's skin. Electro haptic presentation may create highly realistic experience for a user wearing a suit or gloves provided with an electro haptic technology. Almost any sensation can be simulated through the electrical pulses: a temperature change, a pressure change, and a humidity sensation.

It is easy to see from haptic presentation technologies in the current industry that, haptic presentation itself has been a familiar presentation method for users, ranging from vibration haptics commonly used in everyday devices to diversified haptic presentation tailored for specialized fields. However, with the popularization of wearable devices and interactive devices, haptic presentation that the user perceives when consuming media content is no longer limited to basic vibration haptics, but is haptic presentation experience closer to the real world that includes full-body sensations such as vibration, pressure, speed, acceleration, temperature, humidity, and smell.

FIG. 6 is a schematic diagram of a data structure of haptic information representation according to an embodiment of this disclosure.

As shown in FIG. 6, the highest-level data structure of haptic information representation is haptic experience, which is configured for describing all haptic experience information in a file or a bit stream. The haptic experience includes metadata information related to the haptic experience, possible device information, and one or more haptic patterns. The haptic pattern corresponds to a haptic signal of a certain type (for example, vibration, pressure, or temperature), and the haptic pattern includes metadata information related to the haptic pattern, a possibly predefined knowledge event, and one or more haptic channels. The haptic channel includes all or some haptic signals of a corresponding haptic pattern, and the haptic channel includes metadata information related to the haptic channel and one or more haptic events. In some examples, in the same haptic pattern, haptic signals corresponding to different rendering devices may be organized as different haptic channels. The haptic event is a basic haptic signal unit, and the haptic event includes metadata information related to the haptic event and possible haptic event components. A haptic event component is a time-domain component or a frequency-domain component of the haptic event.

The following describes data structures at different levels.

### 1. Haptic Experience

A data structure of the haptic experience is shown in Table 1.

TABLE 1

| Attribute | Description |
|---|---|
| version | indicates standard version information followed by haptic experience. |
| creation_date | indicates creation time of the haptic experience. |
| description | indicates description information of the haptic experience, which is customized |
| | by a user. |
| timescale | timescale of the haptic experience, indicates a quantity of clock units included in |
| | one second. |
| devices | device information element list, indicates one or more pieces of device |
| | information related to the haptic experience. |
| patterns | haptic pattern element list, indicates one or more haptic patterns included in the |
| | haptic experience. |

### 2. Device Information

A data structure of the device information is shown in Table 2.

TABLE 2

| Attribute | Description |
|---|---|
| id | indicates an identifier of a device. |
| device_name | indicates a name (readable by human eyes) of the device. |
| body_parts | indicates a body part corresponding to the device. |

### 3. Haptic Pattern

A data structure of the haptic pattern is shown in Table 3.

TABLE 3

| Attribute | Description |
|---|---|
| id | indicates an identifier of a haptic pattern. |
| pattern_type | indicates a type of the haptic pattern, where possible |
| | values are as follows: |
| | vibration haptics; |
| | pressure; |
| | acceleration; |
| | speed; |
| | temperature; and |
| | electro haptics. |
| refer_devices | indicates a device corresponding to the haptic pattern, and |
| | a value of the field corresponds to an identifier of the |
| | device defined in device information. |
| event_semantics_flag | indicates whether a haptic event corresponds to the haptic |
| | pattern has semantics. |
| event_semantics_type | indicates a specification followed by the semantics of the |
| | haptic event. Possible values of the field are as follows: |
| | the semantics of the haptic event following a specification |
| | defined by this standard; |
| | the semantics of the haptic event following a specification |
| | defined by an external standard; and |
| | the semantics of the haptic event is customized by a user. |
| library_events | knowledge event element list, indicates a knowledge |
| | event included in the haptic pattern. |
| channels | haptic channel element list, indicates a haptic channel |
| | included in the haptic pattern. |

### 4. Haptic Channel

A data structure of the haptic channel is shown in Table 4.

TABLE 4

| Attribute | Description |
|---|---|
| id | indicates an identifier of a haptic channel. |
| description | indicates descriptions of the haptic channel, which are customized by a user. |
| refer_devices | indicates a device corresponding to the haptic pattern, and a value of the field |
| | corresponds to an identifier of the device defined in device information. |
| gain | indicates a gain of the haptic channel, where the gain is applied to all events |
| | included in a current channel, and is configured for restoring a normalized |
| | signal value to an original signal value. |
| | V = gain * x |
| | x is the normalized signal value. |
| events | haptic event element list, indicates a haptic event included in the channel. |

A data structure of the haptic event is shown in Table 5.

TABLE 5

| Attribute | Description |
|---|---|
| id | indicates an identifier of a haptic event. |
| effect_semantic | indicates semantics of the haptic event. When a value of an |
| | event_semantics_flag field in a corresponding pattern is true, the |
| | attribute exists. |
| | The semantics of the haptic event is an event auxiliary information |
| | keyword that describes an intention of a content producer. |
| event_type | indicates a type of the haptic event, where possible values are as follows: |
| | instantaneous event; |
| | continuous event; and |
| | reference event. |
| refer_library_event | When the type of the haptic event is the reference event, the attribute |
| | exists, and indicates a knowledge event identifier corresponding to the |
| | reference event. |
| relative_time | indicates a time offset of the haptic event. |
| duration | indicates duration of the haptic event, and when the event type is the |
| | continuous event, the attribute exists. |
| amplitude | indicates a maximum amplitude value of a signal of the haptic event. |
| base_frequency | indicates a signal reference frequency of the haptic event. |
| event_components | haptic event component element list, indicates components of the haptic |
| | event, where the haptic event components may be a time-domain |
| | component or a frequency-domain component of the haptic event. |

### 5. Haptic Event

The knowledge event is a special haptic event, and a data structure of the knowledge event follows a data structure definition of the haptic event. The knowledge event is usually a predefined haptic event that can be repeatedly cited, to avoid repeated parsing of the same haptic event.

### 6. Haptic Event Component

A data structure of the haptic event component is shown in Table 6.

TABLE 6

| Attribute | Description |
|---|---|
| refer_event_id | indicates an identifier of a haptic event to which a haptic event |
| | component belongs. |
| relative_time | indicates a time offset of the haptic event component relative to the |
| | haptic event. |
| relative_amplitude | indicates an amplitude value ratio of the haptic event component |
| | relative to the haptic event, ranging from 0 to 1. |
| relative_frequency | indicates a frequency offset of the haptic event component relative to |
| | the haptic event. |

It can be known from the foregoing content that haptic presentation can be implemented through transmission of the haptic signal. In some examples, the haptic signal may be defined as the haptic event, and support is provided for decomposing the haptic event into a plurality of haptic event components, thereby implementing transmission of the haptic signal. However, the method of defining the haptic signal may cause excessively poor flexibility of haptic signal representation and excessively large overhead for representation, resulting in problems such as excessively poor user experience of haptic media consumers and excessively large bandwidth consumption of haptic media transmission. For example, there is no clear related solution to how to restore an original haptic signal through the haptic event components and how to deduce a signal value between the haptic event components.

In view of this, embodiments of this disclosure provide a haptic signal interpolation method and apparatus, an electronic device, and a storage medium. Through signal value interpolation, not only different types of haptic signals can be flexibly restored, that is, different types of haptic signals are represented more accurately and flexibly, but also information about haptic event components that needs to be carried in the bit stream can be reduced, that is, overhead for haptic signal representation can be saved on, thereby improving user experience of haptic media consumers and reducing bandwidth consumption of haptic media transmission.

The haptic signal interpolation method provided in this embodiment of this disclosure can be applied to a product related to haptic feedback, and links of an immersive system such as a server end, a player end, and an intermediate node. This is not limited in this disclosure.

The following describes the haptic signal interpolation method provided in the embodiments of this disclosure.

FIG. 7 is a schematic flowchart of a haptic signal interpolation method 200 according to an embodiment of this disclosure. The method 200 may be performed by any electronic device having a data processing capability. For example, the electronic device may be implemented as a terminal, for example, a terminal 110 shown in FIG. 4 or a signal processing device. For ease of description, the following describes the haptic signal interpolation method 200 by using an example in which a decapsulation device performs the haptic signal interpolation method 200.

As shown in FIG. 7, the haptic signal interpolation method 200 may include the following operations:

Operation S210: The decapsulation device determines an interpolation type of a first haptic event component in a first haptic event by decoding a bit stream of a haptic signal.

For example, the haptic signal is a signal configured for conveying haptic experience, and is intended to present a user with a perceptible haptic feedback through a specific device. The haptic signal may include a plurality of modalities, such as vibration, pressure, and temperature, to simulate different haptic sensations. The haptic signal may be rendered and presented on the specific device, so that the user can feel attributes such as a texture, a shape, and a weight of a virtual object or scene by touching, thereby enhancing perception and cognition of a virtual environment. The bit stream of the haptic signal may be a bit stream obtained by encoding an interchange format of the haptic signal, and the bit stream of the haptic signal may also be referred to as a bitstream of the haptic signal. The interchange format of the haptic signal is data of a haptic signal of a specific format. For example, the interchange format of the haptic signal may be JSON data.

In some embodiments, a first haptic event is decomposed into one or more haptic event components, and a first haptic event component is one of the one or more haptic event components into which the first haptic event is decomposed.

FIG. 8 is an example of a format of a bit stream according to an embodiment of this disclosure.

As shown in FIG. 8, the bit stream of the haptic signal may include one or more data units. The data unit may include a head and at least one data packet. For example, the at least one data packet may include a packet 1 to a packet N. Related information of the at least one data packet can be determined by decoding the head. For example, by decoding a type field in the head, it can be determined that the at least one data packet includes a data packet carrying a data structure of the first haptic event, or it is determined that the at least one data packet includes a data packet carrying a data structure of the first haptic event component.

In some embodiments, the interpolation type of the first haptic event component includes at least one of the following: nearest neighbor interpolation, linear interpolation, cubic spline interpolation, Akima interpolation, Bezier interpolation, B-spline interpolation, Lagrange interpolation, Newton interpolation, and custom algorithm interpolation.

The following describes various interpolation types.

Nearest neighbor interpolation assumes that a value of each point is the same as a value of the nearest known point.

Linear interpolation assumes that values between two known points are linear, that is, a midpoint between two points is an average value thereof.

Cubic spline interpolation uses a group of continuous cubic polynomial functions to connect known data points. Endpoints of each polynomial are tangent to two known data points, thereby ensuring continuity and smoothness.

Akima interpolation may be configured for estimating a value of an unknown data point between specified data points. This interpolation method is based on linear interpolation, and a feature of this interpolation method is that a curvature change between data points is considered.

Bezier interpolation is an interpolation method based on a Bezier curve. The Bezier curve is a parameter curve defined by a group of control points, and is configured for smoothly connecting known data points. In Bezier interpolation, a smooth curve passing through the known data points can be generated by adjusting positions and weights of the control points. This method is widely applied to computer graphics, animation production, and other fields, to create a smooth and continuous path and shape.

B-spline interpolation: B-spline interpolation uses a B-spline curve (a parameter curve) to pass through known data points. The B-spline curve is a continuous curve defined by a series of control points.

Lagrange interpolation: Lagrange interpolation uses a Lagrange polynomial to perform interpolation. The Lagrange polynomial is a special interpolation polynomial.

Newton interpolation: Newton interpolation uses a Newton difference polynomial to perform interpolation. In this method, based on a Newton difference formula, a polynomial of an interpolation point is calculated through known data points.

Custom algorithm interpolation: Custom algorithm interpolation refers to using a custom algorithm to perform interpolation calculation based on a specific requirement or problem. This method allows a developer to implement specific interpolation logic as required.

In another alternative embodiment, the interpolation type of the first haptic event component may alternatively be another interpolation type. For example, the interpolation type includes, but is not limited to, the following: Hermite interpolation, a method that can perform interpolation based on given node values and derivative values, and can generate a smooth curve between nodes; polynomial interpolation, which can use a polynomial function to perform interpolation through known data points, where for example, a proper polynomial degree may be selected based on a quantity of known data points; and radial basis function interpolation, which can use a radial basis function to estimate a value of an unknown point, where the radial basis function is a function that calculates a weight based on a distance, and is configured to perform interpolation between known data points.

Operation S220: The decapsulation device performs signal value interpolation between a signal value of the first haptic event component and a signal value of a second haptic event component based on the interpolation type of the first haptic event component, to obtain the haptic signal.

The second haptic event component is a haptic event component preceding or following the first haptic event component.

For example, the second haptic event component is the haptic event component preceding or following the first haptic event component in the first haptic event.

For example, the decapsulation device performs signal value interpolation between the signal value of the first haptic event component and the signal value of the second haptic event component preceding or following the first haptic event component based on the interpolation type of the first haptic event component. For example, the decapsulation device can interpolate one or more signal values and obtain the haptic signal based on existing signal values (to be specific, signal values of haptic signal components in the first haptic event, which include the signal value of the first haptic event component and the signal value of the second haptic event component). In other words, in this example, the second haptic event component is a haptic event component in the first haptic event.

For example, the second haptic event component may be the haptic event preceding or following the first haptic event component in a decoding order of the haptic event components in the first haptic event. For example, the second haptic event component may be the 1^{st} haptic event preceding or following the first haptic event component in the decoding order of the haptic event components in the first haptic event.

In this embodiment, through signal value interpolation, the decapsulation device not only can flexibly restore different types of haptic signals, that is, represent different types of haptic signals more accurately and flexibly, but also can reduce information about haptic event components that needs to be carried in the bit stream, that is, can save on overhead for haptic signal representation, thereby improving user experience of haptic media consumers and reducing bandwidth consumption of haptic media transmission.

In some embodiments, operation S210 may include operations of S210-A and S210-B:

Operation S210-A: The decapsulation device acquires a first identifier by decoding the bit stream, the first identifier being configured for indicating an interpolation type.

Operation S210-B: The decapsulation device determines the interpolation type of the first haptic event component based on the interpolation type indicated by the first identifier.

For example, if a value of the first identifier is a first value, the interpolation type indicated by the first identifier may be an interpolation type corresponding to the first value. Different values may correspond to different interpolation types. For example, a correspondence between the first value and the interpolation type may be shown as follows:
0: nearest neighbor interpolation.
1: linear interpolation.
2: cubic spline interpolation
3: Akima interpolation.
4: Bezier interpolation.
5: B-spline interpolation.
6: Lagrange interpolation.
7: Newton interpolation.
8: custom algorithm interpolation.

In some embodiments, operation S210-A in which the decapsulation device acquires the first identifier by decoding the bit stream may be implemented as follows:

The decapsulation device acquires a second identifier by decoding the bit stream; and acquires the first identifier by decoding the bit stream when the second identifier indicates that the first identifier exists.

For example, the decapsulation device acquires the second identifier by decoding the bit stream, where the second identifier is configured for indicating whether the first identifier exists in the bit stream; and acquires the first identifier by decoding the bit stream when the second identifier indicates that the first identifier exists.

When the second identifier indicates that the first identifier does not exist, it indicates that the bit stream does not include the first identifier. In this case, the decapsulation device may determine a default interpolation type as the interpolation type of the first haptic event component. Alternatively, it may be considered unnecessary to perform interpolation between the signal value of the first haptic event component and the signal value of the second haptic event component.

Certainly, in another alternative embodiment, the second identifier may alternatively be configured for indicating whether to perform interpolation between the signal value of the first haptic event component and the signal value of the second haptic event component. For example, when the second identifier indicates that interpolation is performed between the signal value of the first haptic event component and the signal value of the second haptic event component, the decapsulation device can directly determine the default interpolation type as the interpolation type of the first haptic event component. In other words, the decapsulation device can acquire the second identifier by decoding the bit stream, and can determine the interpolation type of the first haptic event component through the second identifier without the need to acquire the first identifier described above by decoding the bit stream.

In some embodiments, operation S210-A in which the decapsulation device acquires the first identifier by decoding the bit stream may be implemented as follows:

The decapsulation device acquires a third identifier by decoding the bit stream; and acquires the first identifier by decoding the bit stream when the third identifier indicates that the first haptic event is a continuous event.

For example, the decapsulation device acquires the third identifier by decoding the bit stream. The third identifier is configured for indicating whether the first haptic event is the continuous event. When the third identifier indicates that the first haptic event is the continuous event, the decapsulation device acquires the first identifier by decoding the bit stream. When the third identifier indicates that the first haptic event is not the continuous event, the bit stream does not include the first identifier. In this case, the default interpolation type may be determined as the interpolation type of the first haptic event component. Alternatively, it may be considered unnecessary to perform interpolation between the signal value of the first haptic event component and the signal value of the second haptic event component.

In some embodiments, operation S210-A in which the decapsulation device acquires the first identifier by decoding the bit stream may be implemented as follows:

The decapsulation device acquires the data structure of the first haptic event by decoding the bit stream, the data structure of the first haptic event including the first identifier.

Correspondingly, operation S210-B in which the decapsulation device determines the interpolation type of the first haptic event component based on the interpolation type indicated by the first identifier may be implemented as follows:

The decapsulation device determines the interpolation type indicated by the first identifier as an interpolation type of some or all haptic event components in the first haptic event, the some or all haptic event components including the first haptic event component.

For example, the decapsulation device determines the interpolation type indicated by the first identifier as an interpolation type of some haptic event components in the first haptic event, the some haptic event components including the first haptic event component. For example, the some haptic event components may be all haptic event components in the first haptic event except the last haptic event component. For another example, the some haptic event components may be haptic event components at preset positions in the first haptic event. For example, the first haptic event component may be a haptic event component located at the first position, a middle position, or the last position in the decoding order of the haptic event components in the first haptic event. In other words, the first haptic event component is any one of haptic event components at the first position, the middle position, or the last position. Certainly, the first position, the middle position, or the last position are merely examples of the preset position and are not to be understood as a limitation to the embodiments of this disclosure.

For example, the decapsulation device determines the interpolation type indicated by the first identifier as an interpolation type of all haptic event components in the first haptic event. In other words, the first haptic event component may be any haptic event component in the first haptic event.

For example, the data structure of the first haptic event may also be referred to as attribute information of the first haptic event, an element of the first haptic event, or an interchange format of the first haptic event. The data structure of the first haptic event includes related information of the first haptic event, which includes, but is not limited to, metadata of the first haptic event and a haptic event component list of the first haptic event. Each haptic event component in the haptic event component list may be configured for determining a signal value at a position of the haptic signal.

In this embodiment, the data structure of the first haptic event includes the first identifier, meaning that the first identifier can be applied to one or more haptic event components in the first haptic event, which can reduce a data volume configured for determining the interpolation type the haptic event components in the bit stream, thereby improving data transmission efficiency and saving on transmission resources of the first identifier.

For example, the data structure of the first haptic event may be as shown in Table 7.

TABLE 7

| | | Default | | |
|---|---|---|---|---|
| Attribute | Data type | value | Description | Mandatory |
| id | integer | None | indicates an identifier of a | Yes |
| | | | haptic event. | |
| effect_semantic | string | None | indicates semantics of the | Conditionally |
| | | | haptic event. When a value of | mandatory |
| | | | an event_semantics_flag field | |
| | | | in a corresponding pattern is | |
| | | | true, the attribute exists. | |
| | | | The semantics of the haptic | |
| | | | event is an event auxiliary | |
| | | | information keyword that | |
| | | | describes an intention of a | |
| | | | content producer. | |
| event_type | enum<string> | None | indicates a type of the haptic | Yes |
| | | | event, where possible values | |
| | | | are as follows: | |
| | | | instantaneous event; | |
| | | | continuous event; and | |
| | | | reference event. | |
| refer_library_event | integer | None | When the type of the haptic | Conditionally |
| | | | event is the reference event, | mandatory |
| | | | the attribute exists, and | |
| | | | indicates a knowledge event | |
| | | | identifier corresponding to the | |
| | | | reference event. | |
| relative_time | integer | None | indicates a time offset of the | Yes |
| | | | haptic event. | |
| duration | integer | None | indicates duration of the | Conditionally |
| | | | haptic event, and when the | mandatory |
| | | | event type is the continuous | |
| | | | event, the attribute exists. | |
| amplitude | integer | None | indicates a maximum | Yes |
| | | | amplitude value of a signal of | |
| | | | the haptic event. | |
| base_frequency | integer | None | indicates a signal reference | Yes |
| | | | frequency of the haptic event. | |
| interpolation_flag | bool | None | Whether to indicate an | No |
| | | | interpolation type. When a | |
| | | | value of the field is 1, a signal | |
| | | | interpolation type is | |
| | | | indicated; and when the value | |
| | | | of the field is 0, the signal | |
| | | | interpolation type is not | |
| | | | indicated. | |
| interpolation_type | integer | None | indicates the interpolation | No |
| | | | type, where possible values | |
| | | | are as follows: | |
| | | | 0: nearest neighbor | |
| | | | interpolation; | |
| | | | 1: linear interpolation; | |
| | | | 2: cubic spline interpolation; | |
| | | | 3: Akima interpolation; | |
| | | | 4: Bezier interpolation; | |
| | | | 5: B-spline interpolation; | |
| | | | 6: Lagrange interpolation; | |
| | | | 7: Newton interpolation; | |
| | | | 8: custom algorithm | |
| | | | interpolation. | |
| event_components | array<AVS_hap- | None | haptic event component | No |
| | tics_event_component> | | element list, indicates | |
| | | | components of the haptic | |
| | | | event, where the haptic event | |
| | | | components may be a time- | |
| | | | domain component or a | |
| | | | frequency-domain component | |
| | | | of the haptic event. | |

As shown in Table 7, the first identifier is an interpolation_type field, and the second identifier is an interpolation_flag field. When a value of the interpolation_flag field in the data structure of the first haptic event is 1, the interpolation_type field indicated in the data structure of the first haptic event is effective for all haptic event components of the first haptic event. The knowledge event is a special haptic event, and a data structure of the knowledge event follows a data structure definition of the haptic event. The knowledge event is usually a predefined haptic event that can be repeatedly cited, to avoid repeated parsing of the same haptic event.

In some embodiments, operation S210-A in which the decapsulation device acquires the first identifier by decoding the bit stream may be implemented as follows:

The decapsulation device acquires the data structure of the first haptic event component by decoding the bit stream, the data structure of the first haptic event component including the first identifier. Correspondingly, operation S210-B in which the decapsulation device determines the interpolation type of the first haptic event component based on the interpolation type indicated by the first identifier may be implemented as follows:

The decapsulation device determines the interpolation type indicated by the first identifier as the interpolation type of the first haptic event component.

For example, the data structure of the first haptic event component may also be referred to as attribute information of the first haptic event component, an element of the first haptic event component, or an interchange format of the first haptic event component. The data structure of the first haptic event component includes a time-domain component or a frequency-domain component of a signal value of the haptic signal.

In this embodiment, the data structure of the first haptic event component includes the first identifier, meaning that the first identifier is only applicable to the first haptic event, which can improve flexibility of the interpolation type of the haptic event components in the first haptic event.

In some embodiments, the method 200 in this embodiment of this disclosure may further include the following operations:

The decapsulation device determines the interpolation type indicated by the first identifier as an interpolation type of a haptic event component following the first haptic event component until a data structure in the first haptic event includes a new haptic event component of the first identifier or the last haptic event component in the first haptic event.

For example, the decapsulation device determines the interpolation type indicated by the first identifier as the interpolation type of the first haptic event component and the interpolation type of the haptic event component following the first haptic event component until the data structure in the first haptic event includes a haptic event component with a new first identifier or the last haptic event component in the first haptic event. In some examples, if the decapsulation device obtains, after the first haptic event component in the decoding order of the haptic event components in the first haptic event, a third haptic event component whose data structure includes a new first identifier through decoding, the decapsulation device can determine an interpolation type indicated by the new first identifier as an interpolation type of the third haptic event component. If the decapsulation device does not transmit the new first identifier after the first haptic event component in the decoding order of the haptic event components in the first haptic event until the last haptic event component in the first haptic event is decoded, the first identifier is applicable to all haptic event components after the first haptic event component. In other words, an interpolation type from the first haptic event component to the last haptic event component (for example, including the first haptic event component and the last haptic event component) is the interpolation type indicated by the first identifier that is included in the data structure of the first haptic event component.

In this embodiment, the decapsulation device interrupts application of the first identifier through the haptic event component with the new first identifier or the last haptic event component in the first haptic event. This not only can reduce a data volume configured for determining the interpolation type of the haptic event components in the bit stream, thereby improving data transmission efficiency and saving on transmission resources of the first identifier, but also can improve flexibility of the interpolation type of the haptic event components in the first haptic event.

For example, the data structure of the first haptic event component may be as shown in Table 8.

TABLE 8

| | | Default | | Mandator |
|---|---|---|---|---|
| Attribute | Data type | value | Description | y |
| refer_event_id | integer | None | indicates an identifier of a haptic event to | Yes |
| | | | which a haptic event component belongs. | |
| interpolation_flag | bool | None | Whether to indicate an interpolation type. | No |
| | | | When a value of the field is 1, a signal | |
| | | | interpolation type is indicated; and when | |
| | | | the value of the field is 0, the signal | |
| | | | interpolation type is not indicated. | |
| interpolation_type | integer | None | indicates the interpolation type, where | No |
| | | | possible values are as follows: | |
| | | | 0: nearest neighbor interpolation; | |
| | | | 1: linear interpolation; | |
| | | | 2: cubic spline interpolation; | |
| | | | 3: Akima interpolation; | |
| | | | 4: Bezier interpolation; | |
| | | | 5: B-spline interpolation; | |
| | | | 6: Lagrange interpolation; | |
| | | | 7: Newton interpolation; | |
| | | | 8: custom algorithm interpolation. | |
| relative_time | integer | None | indicates a time offset of the haptic event | No |
| | | | component relative to the haptic event. | |
| relative_amplitude | number | None | indicates an amplitude value ratio of the | No |
| | | | haptic event component relative to the | |
| | | | haptic event, ranging from 0 to 1. | |
| relative_frequency | integer | None | indicates a frequency offset of the haptic | No |
| | | | event component relative to the haptic | |
| | | | event. | |

As shown in Table 8, the first identifier is the interpolation_type field, and the second identifier is the interpolation_flag field. Assuming that the first haptic event includes N haptic event components, if a value of the interpolation_flag field in a data structure of an i^{th} haptic event component is 1, a corresponding interpolation_type field is continuously effective until a new interpolation_type field appears or until the last haptic event component in the N haptic event components is encountered.

In some embodiments, operation S220 in which the decapsulation device performs signal value interpolation between the signal value of the first haptic event component and the signal value of the second haptic event component preceding or following the first haptic event component based on the interpolation type of the first haptic event component, to obtain the haptic signal, may be implemented as follows:

The decapsulation device uses the interpolation type of the first haptic event component to perform interpolation between the signal value of the first haptic event component and the signal value of the second haptic event component based on the signal value of the first haptic event component, to obtain the haptic signal.

For example, the decapsulation device may use the interpolation type (that is, an interpolation method) of the first haptic event component to perform interpolation between the signal value of the first haptic event component and the signal value of the second haptic event component by using the signal value of the first haptic event component as an input, to obtain the haptic signal. For example, assuming that the interpolation type of the first haptic event component is nearest neighbor interpolation, the decapsulation device may use the signal value of the first haptic event component as a nearest neighbor signal value by using nearest neighbor interpolation, and interpolate the nearest neighbor signal value between the signal value of the first haptic event component and the signal value of the second haptic event component, to obtain the haptic signal.

For example, the decapsulation device may perform interpolation between the signal value of the first haptic event component and the signal value of the second haptic event component based on the signal value of the first haptic event component and the signal value of the second haptic event component and using the interpolation type of the first haptic event component, to obtain the haptic signal. For example, assuming that the interpolation type of the first haptic event component is linear interpolation, the decapsulation device can determine an average value of the signal value of the first haptic event component and the signal value of the second haptic event component, and interpolate the average value between the signal value of the first haptic event component and the signal value of the second haptic event component, to obtain the haptic signal.

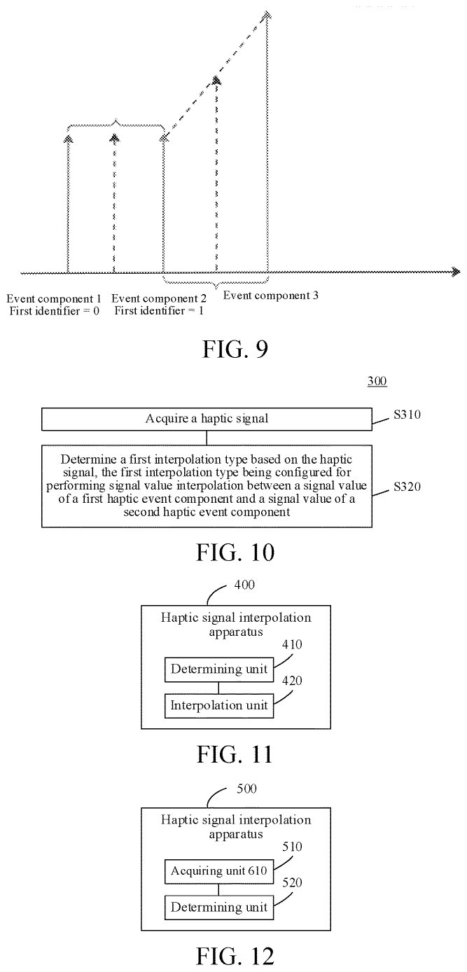

FIG. 9 is an example of an interpolation principle according to an embodiment of this disclosure.

As shown in FIG. 9, assuming that the first haptic event includes a haptic event component 1 to a haptic event component 3, an interpolation type of the haptic event component 1 is nearest neighbor interpolation, and an interpolation type of a haptic event component 2 is linear interpolation, the decapsulation device can use a signal value of the haptic event component 1 as the nearest neighbor signal value by using nearest neighbor interpolation, and interpolate the nearest neighbor signal value between the signal value of the haptic event component 1 and the signal value of the haptic event component 2. In addition, the decapsulation device can determine an average value of signal values of the haptic event component 2 and the haptic event component 3, and interpolate a linear signal value between a signal value of the haptic event component 2 and a signal value of the haptic event component 3. Then, the decapsulation device obtains the haptic signal based on signal values from the haptic event component 1 to the haptic event component 3 and two interpolated signal values.

Certainly, in another alternative embodiment, the decapsulation device may alternatively perform interpolation between the signal value of the first haptic event component and the signal value of the second haptic event component based on the signal value of the second haptic event component and using the interpolation type of the first haptic event component, to obtain the haptic signal. For example, assuming that the interpolation type of the first haptic event component is nearest neighbor interpolation, the decapsulation device may use the signal value of the second haptic event component as the nearest neighbor signal value by using nearest neighbor interpolation, and interpolate the nearest neighbor signal value between the signal value of the first haptic event component and the signal value of the second haptic event component, to obtain the haptic signal. For example, the decapsulation device can determine the signal value of the first haptic event component or the signal value of the second haptic event component based on an application scenario of the first haptic event, and perform interpolation between the signal value of the first haptic event component and the signal value of the second haptic event component using the interpolation type of the first haptic event component.

In some embodiments, before operation S210, the method 200 may further include the following operations:

The decapsulation device receives a haptic media file transmitted by an encapsulation device, and decapsulate the haptic media file, to obtain the bit stream; or receives a haptic media segment transmitted by the encapsulation device, and decapsulate the haptic media segment, to obtain the bit stream; or receives a haptic media track transmitted by a file encapsulation device, and decapsulate the haptic media track, to obtain the bit stream.

For example, the decapsulation device can receive three different types of haptic media encapsulation data: the haptic media file, the haptic media segment, and the haptic media track. The data is transmitted by the encapsulation device. All of the file, the segment, and the track use an encapsulation format. This encapsulation format is intended to facilitate data transmission and storage. When receiving the encapsulated data, the decapsulation device needs to perform a decapsulation operation to obtain the bit stream. Decapsulation is a reverse process, and an objective of decapsulation is to remove the encapsulation format, to restore or extract an original data stream. A specific decapsulation method may vary depending on different encapsulation formats.

A decoding process of the bit stream is exemplarily described below based on Table 9 and Table 10 with reference to the first identifier, the second identifier, and the third identifier described in this disclosure.

TABLE 9

| Syntax | No. of bits | Mnemonic |
|---|---|---|
| readEvent( ) { | | |
| eventId | 16 | uimsbf |
| eventType; | 4 | uimsbf |
| eventSementicsFlag | 1 | bool |
| if (eventSementicsFlag) { | | |
| semanticKeywords | 12 | uimsbf |
| } | | |
| if (eventType == 2) { | | |
| referEventId; | 16 | uimsbf |
| } | | |
| interpolationFlag | 1 | bool |
| if (interpolationFlag == 1) { | | |
| interpolationType; | 4 | uimsbf |
| } | | |
| relativePosition | 32 | imsbf |
| if (eventType == 1) { | | |
| duration; | 32 | uimsbf |
| } | | |
| amplitude | 8 | uimsbf |
| baseFrequency | 16 | uimsbf |
| numComponents | 16 | uimsbf |
| for (i = 0; i < numComponents; i++) { | | |
| readEventComponent( ); | | |
| } | | |
| } | | |

Semantics of each field in Table 9 is as follows:

eventId: eventId indicates an identifier of a haptic event.

eventType: eventType indicates a type of the haptic event. When a value of the field is 0, the event is an instantaneous event. When the value of the field is 1, the event is a continuous event. When the value of the field is 2, the event is a reference event.

eventSementicsFlag: eventSementicsFlag does not indicate semantics of the haptic event when a value is 0; and indicates the semantics of the haptic event when the value is 1.

semanticKeywords: semanticKeywords indicates the semantics of the event. The semantics of the haptic event is an event auxiliary information keyword that describes an intention of a content producer.

referenEventId: referenEventId indicates a knowledge event identifier corresponding to the reference event.

interpolationFlag: Whether to indicate an interpolation type. When a value of the field is 1, a signal interpolation type is indicated; and when the value of the field is 0, the signal interpolation type is not indicated.

interpolationType: interpolationType indicates an interpolation type, where possible values are as follows:
0: nearest neighbor interpolation;
1: linear interpolation;
2: cubic spline interpolation;
3: Akima interpolation;
4: Bezier interpolation;
5: B-spline interpolation;
6: Lagrange interpolation;
7: Newton interpolation;
8: custom algorithm interpolation.

relativePosition: relativePosition indicates a time or space offset of the haptic event.

duration: duration indicates duration of the haptic event. When the event type is the continuous event, the attribute exists.

amplitude: amplitude indicates a maximum amplitude value of a signal of the haptic event.

baseFrequency: baseFrequency indicates a signal base frequency of the haptic event.

numComponents: numComponents indicates a quantity of haptic event components, where a haptic event component may be a time-domain component or a frequency-domain component of the haptic event.

In some examples, readEvent ( ) is a function for processing the haptic event, and is configured for reading and parsing various attributes of the haptic event from an input. First, a unique identifier eventId of the haptic event is read and stored. Next, eventType is read, which indicates a type of the haptic event. Then, eventSementicsFlag is read. This flag bit is usually configured for indicating whether the haptic event has semantic information. If a value of eventSementicsFlag is true (non-zero), semantic keywords semanticKeywords can be further read and stored. Then, the function checks whether a value of the eventType is equal to 2. If the value is equal to 2, it indicates that this is a reference event, and therefore, the reference event ID referenEventId can be read and stored. The reference event is usually configured for describing a relationship between an event and another event. Next, the function reads interpolationFlag. If a value of interpolationFlag is 1, an interpolation type is indicated, and then the interpolation type interpolation Type can be read and stored. Interpolation is a mathematical method, configured for estimating a new data point between two discrete data points. When eventType is equal to 1, the function can read and store the duration of the haptic event. Finally, the function reads and stores an amplitude value amplitude of the haptic event, a base frequency baseFrequency, and the quantity of haptic event components numComponents. These attributes provide more information about a haptic signal. Once all attributes are read, the function processes each haptic event component through a for loop (from i=0 to i<numComponents). In a loop body, a function named readEventComponent ( ) is called, and this function may be responsible for reading and processing a single haptic event component. The first identifier in the foregoing is the interpolation_type field, the second identifier in the foregoing is the interpolation_flag field, and the third identifier in the foregoing is the eventType field.

TABLE 10

| Syntax | No. of bits | Mnemonic |
|---|---|---|
| readEventComponent( ) { | | |
| referEventId | 16 | uimsbf |
| interpolationFlag | 1 | bool |
| if (interpolationFlag == 1) { | | |
| interpolation Type; | 4 | uimsbf |
| } | | |
| relative_position; | 8 | uimsbf |
| relative_amplitude; | 16 | uimsbf |
| relative_frequency; | 16 | uimsbf |
| } | | |

Semantics of each field in Table 10 is as follows:

referenEventId: referenEventId indicates an identifier of a haptic event to which a haptic event component belongs.

interpolationFlag: Whether to indicate an interpolation type. When a value of the field is 1, a signal interpolation type is indicated; and when the value of the field is 0, the signal interpolation type is not indicated.

interpolationType: interpolationType indicates an interpolation type, where possible values are as follows:
0: nearest neighbor interpolation;
1: linear interpolation;
2: cubic spline interpolation;
3: Akima interpolation;
4: Bezier interpolation;
5: B-spline interpolation;
6: Lagrange interpolation;
7: Newton interpolation;
8: custom algorithm interpolation.

relative_position: relative_position indicates a time or space offset of the haptic event component relative to the haptic event.

relative_amplitude: relative_amplitude indicates an amplitude value ratio of the haptic event component relative to the haptic event, ranging from 0 to 1.

relative_frequency: relative_frequency indicates a frequency offset of the haptic event component relative to the haptic event.

In some examples, readEventComponent ( ) is an auxiliary function, and is configured for reading and processing a single haptic event component of the haptic event. First, a reference event ID referenEventId is read and stored. The reference event ID is an identifier of another event relative to a current event, and is configured for describing a relationship between events. Next, interpolationFlag is read. If a value of interpolationFlag is 1, the component indicates an interpolation type, and then the interpolation type interpolationType is read and stored. The interpolation type defines an interpolation method and parameter. Then, the function reads relative_position, where relative_position represents relative_position information of the component in the haptic event. Next, the function reads relative_amplitude. relative_amplitude represents relative amplitude information of the component in the haptic event. Finally, the function reads relative_frequency. relative_frequency represents relative frequency information of the component in the haptic event. The first identifier in the foregoing is the interpolation_type field, the second identifier in the foregoing is the interpolation_flag field, and the third identifier in the foregoing is the eventType field.

The exemplary implementations of this disclosure are described in detail above with reference to the accompanying drawings. However, this disclosure is not limited to the specific details in the implementations described above, a plurality of simple deformations may be made to the technical solution of this disclosure within a range of the technical concept of this disclosure, and these simple deformations fall within the protection scope of this disclosure. For example, the specific technical features described in the foregoing specific implementations may be combined in any proper manner in a case without conflict. To avoid unnecessary repetition, this disclosure does not describe any possible combination manner. For another example, different implementations of this disclosure may also be arbitrarily combined without departing from the idea of this disclosure, and these combinations shall still be regarded as content disclosed in this disclosure.

In various method embodiments of this disclosure, an order of sequence numbers of the foregoing particular processes does not indicate an execution sequence, and execution sequences of the processes are to be determined according to functions and internal logics thereof and are not to impose any limitation on an implementation process of the embodiments of this disclosure.

The following describes a haptic signal interpolation method provided in this embodiment of this disclosure from the perspective of a device side configured for encoding or encapsulating a haptic signal.

FIG. 10 is a schematic flowchart of a haptic signal interpolation method 300 according to an embodiment of this disclosure. The method 300 may be performed by any electronic device having a data processing capability. For example, the electronic device may be implemented as a server, for example, the server 120 shown in FIG. 4 or a signal processing device. For ease of description, the following describes the haptic signal interpolation method 300 by using an example in which an encapsulation device performs the haptic signal interpolation method 300.

As shown in FIG. 10, the haptic signal interpolation method 300 may include the following operations:

Operation S310: The encapsulation device acquires a haptic signal.

Operation S320: The encapsulation device determines a first interpolation type based on the haptic signal, the first interpolation type being configured for performing signal value interpolation between a signal value of a first haptic event component and a signal value of a second haptic event component in a first haptic event, and the second haptic event component being a haptic event component preceding or following the first haptic event component.

In some embodiments, the method 300 may further include the following operation:

The encapsulation device encodes a first identifier, to obtain a bit stream of the haptic signal, the first identifier being configured for indicating the first interpolation type.

In some embodiments, the method 300 may further include the following operation:

The encapsulation device encodes a second identifier or a third identifier, the second identifier being configured for indicating whether the first identifier exists, and the third identifier being configured for indicating whether the first haptic event is a continuous event.

In some embodiments, the encapsulation device encodes the first identifier, to obtain the bit stream of the haptic signal, which may be implemented as follows:

The encapsulation device encodes a data structure of the first haptic event and a data structure of the first haptic event component, to obtain the bit stream, where
the data structure of the first haptic event includes the first identifier, or the data structure of the first haptic event component includes the first identifier.

In some embodiments, the method 300 may further include the following operation:

The encapsulation device encapsulates the bit stream, to obtain a haptic media file of the haptic signal.

The encapsulation device transmits the haptic media file, a haptic media file segment in the haptic media file, or a haptic media track in the haptic media file to a decapsulation device.

In some embodiments, the interpolation type of the first haptic event component includes at least one of the following: nearest neighbor interpolation, linear interpolation, cubic spline interpolation, Akima interpolation, Bezier interpolation, B-spline interpolation, Lagrange interpolation, Newton interpolation, and custom algorithm interpolation.

It is to be understood that, the method 300 may be understood as a reverse process of the method 200. To be specific, in the method 300, the encapsulation device manufactures or collects the haptic signal based on an expected haptic media effect, and generates an interchange format of the haptic signal. For a continuous haptic signal, an interpolation type of a haptic event component can be selected through the haptic signal (for example, a signal value of an interpolation point), and the interpolation type is indicated in a haptic event or the haptic event component. The encapsulation device compresses the interchange format of the haptic signal into the bit stream of the haptic signal. The encapsulation device encapsulates the bit stream of the haptic signal into the haptic media file, and the haptic media file includes one or more haptic media tracks. In one embodiment, the encapsulation device can slice the haptic media file into a plurality of haptic media file segments. In some examples, for a specific solution of the method 300, refer to related content of the method 200. To avoid repetition, details are not described herein again.

The following describes an apparatus provided in this embodiment of this disclosure.

FIG. 11 is a schematic block diagram of a haptic signal interpolation apparatus 400 according to an embodiment of this disclosure, which is applied to a decapsulation device or a signal processing device.

As shown in FIG. 11, the haptic signal interpolation apparatus 400 may include:
a determining unit 410, configured to determine an interpolation type of a first haptic event component in a first haptic event by decoding a bit stream of a haptic signal; and
an interpolation unit 420, configured to perform signal value interpolation between a signal value of the first haptic event component and a signal value of a second haptic event component based on the interpolation type of the first haptic event component, to obtain the haptic signal, the second haptic event component being a haptic event component preceding or following the first haptic event component.

In some embodiments, the determining unit 410 is configured to:
acquire a second identifier by decoding the bit stream, the second identifier being configured for indicating whether the first identifier exists; and
determine the interpolation type of the first haptic event component based on the interpolation type indicated by the first identifier.

In some embodiments, the determining unit 410 is configured to:
acquire a second identifier by decoding the bit stream; and
acquire the first identifier by decoding the bit stream when the second identifier indicates that the first identifier exists.

In some embodiments, the determining unit 410 is configured to:
acquire a third identifier by decoding the bit stream, the third identifier being configured for indicating whether the first haptic event is a continuous event; and
acquire the first identifier by decoding the bit stream when the third identifier indicates that the first haptic event is the continuous event.

In some embodiments, the determining unit 410 is configured to:
acquire a data structure of the first haptic event by decoding the bit stream, the data structure of the first haptic event including the first identifier; and
determine the interpolation type indicated by the first identifier as an interpolation type of some or all haptic event components in the first haptic event, the some or all haptic event components including the first haptic event component.

In some embodiments, the determining unit 410 is configured to:
acquire a data structure of the first haptic event component by decoding the bit stream, the data structure of the first haptic event component including the first identifier; and
determine the interpolation type indicated by the first identifier as the interpolation type of the first haptic event component.

In some embodiments, the determining unit 410 is further configured to:
determine the interpolation type indicated by the first identifier as an interpolation type of a haptic event component following the first haptic event component until a data structure in the first haptic event includes a new haptic event component of the first identifier or the last haptic event component in the first haptic event.

In some embodiments, the interpolation unit 420 is configured to:
perform interpolation between the signal value of the first haptic event component and the signal value of the second haptic event component based on the signal value of the first haptic event component and using the interpolation type of the first haptic event component, to obtain the haptic signal.

In some embodiments, the interpolation type of the first haptic event component includes at least one of the following: nearest neighbor interpolation, linear interpolation, cubic spline interpolation, Akima interpolation, Bezier interpolation, B-spline interpolation, Lagrange interpolation, Newton interpolation, and custom algorithm interpolation.

In some embodiments, before determining the interpolation type of the first haptic event component in the first haptic event, the determining unit 410 is further configured to:
receive a haptic media file transmitted by an encapsulation device, and decapsulate the haptic media file, to obtain the bit stream; or receive a haptic media segment transmitted by the encapsulation device, and decapsulate the haptic media segment, to obtain the bit stream; or receive a haptic media track transmitted by a file encapsulation device, and decapsulate the haptic media track, to obtain the bit stream.

The apparatus embodiments and the method embodiments can correspond to each other, and for similar descriptions, refer to the method embodiments. In some examples, the haptic signal interpolation apparatus 400 may correspond to a corresponding body in performing the method 200 in this embodiment of this disclosure, and units in the haptic signal interpolation apparatus 400 are respectively configured to implement corresponding procedures in the method 200. For brevity, details are not described herein again.

FIG. 12 is a schematic block diagram of a haptic signal interpolation apparatus 500 according to an embodiment of this disclosure, which is applied to an encapsulation device or a signal processing device.

As shown in FIG. 12, the haptic signal interpolation apparatus 500 may include:
an acquiring unit 510, configured to acquire a haptic signal; and
a determining unit 520, configured to determine a first interpolation type based on the haptic signal, the first interpolation type being configured for performing signal value interpolation between a signal value of a first haptic event component and a signal value of a second haptic event component in a first haptic event, and the second haptic event component being a haptic event component preceding or following the first haptic event component.

In some embodiments, the determining unit 520 is further configured to:
encode a first identifier, to obtain a bit stream of the haptic signal, the first identifier being configured for indicating the first interpolation type.

In some embodiments, the determining unit 520 is further configured to:
encode a second identifier or a third identifier, the second identifier being configured for indicating whether the first identifier exists, and the third identifier being configured for indicating whether the first haptic event is a continuous event.

In some embodiments, the determining unit 520 is configured to:
encode a data structure of the first haptic event and a data structure of the first haptic event component, to obtain the bit stream,
the data structure of the first haptic event including the first identifier, or the data structure of the first haptic event component including the first identifier.

In some embodiments, the determining unit 520 is further configured to:
encapsulate the bit stream, to obtain a haptic media file of the haptic signal; and
transmit the haptic media file, a haptic media file segment in the haptic media file, or a haptic media track in the haptic media file to a decapsulation device.

In some embodiments, an interpolation type of the first haptic event component includes at least one of the following: nearest neighbor interpolation, linear interpolation, cubic spline interpolation, Akima interpolation, Bezier interpolation, B-spline interpolation, Lagrange interpolation, Newton interpolation, and custom algorithm interpolation.

The apparatus embodiments and the method embodiments can correspond to each other, and for similar descriptions, refer to the method embodiments. In some examples, the haptic signal interpolation apparatus 500 may correspond to a corresponding body in performing the method 300 in this embodiment of this disclosure, and units in the haptic signal interpolation apparatus 500 are respectively configured to implement corresponding procedures in the method 300. For brevity, details are not described herein again.

The units in the haptic signal interpolation apparatus 400 or 500 described in this embodiment of this disclosure are divided based on logical functions. In an actual application, a function of one unit may be implemented by a plurality of units, or functions of a plurality of units are implemented by one unit, or even these functions may be cooperatively implemented by one or more other units. For example, some or all of the haptic signal interpolation apparatus 400 or 500 is combined into one or several other units. For another example, one (or more) of the units in the haptic signal interpolation apparatus 400 or 500 may be further divided into a plurality of units of smaller functions. In this way, same operations can be implemented without affecting implementation of the technical effects of the embodiments of this disclosure. For another example, the haptic signal interpolation apparatus 400 or 500 may also include another unit. In an actual application, these functions may also be cooperatively implemented by another unit and may be cooperatively implemented by a plurality of units.

In this embodiment of this disclosure, the term “module” or “unit” refers to a computer program or a part of the computer program that has a preset function, which works together with other relevant parts to achieve a preset objective, and may be wholly or partially implemented by using software, hardware (such as a processing circuit or a memory), or a combination thereof. Similarly, one processor (or a plurality of processors or memories) can be configured to implement one or more modules or units. In addition, each module or unit may be a part of an overall module or unit including a function of the module or unit.

According to another embodiment of this disclosure, the haptic signal interpolation apparatus 400 or 500 described in the embodiments of this disclosure may be constructed and methods in the embodiments of this disclosure may be implemented by running a computer program (including program code) that can perform operations described in the corresponding methods on a general-purpose computing device of a general-purpose computer including processing elements and storage elements such as a central processing unit (CPU), a random access storage medium (RAM), and a read-only medium (ROM). The computer program may be recorded in, for example, a computer-readable storage medium, and may be loaded into the electronic device by using the computer-readable storage medium. The computer program is configured to implement the corresponding methods in the embodiments of this disclosure. In other words, the units described above may be implemented in a form of hardware, or may be implemented in a form of software instructions, or may be implemented in a form of a combination of software and hardware. In some examples, operations of the method embodiments in the embodiments of this disclosure may be completed through hardware integrated logic circuits and/or software instructions in the processor. The operations of the methods disclosed with reference to the embodiments of this disclosure may be directly performed and completed by using a hardware decoding processor, or may be performed and completed by using a combination of hardware and software in the decoding processor. In one embodiment, the software may be located in a mature storage medium in the art, such as a random access memory, a flash memory, a read-only memory, a programmable read-only memory, an electrically-erasable programmable memory, or a register. The software in the memory may be run by using the processor, to complete the operations in the method embodiments described above.

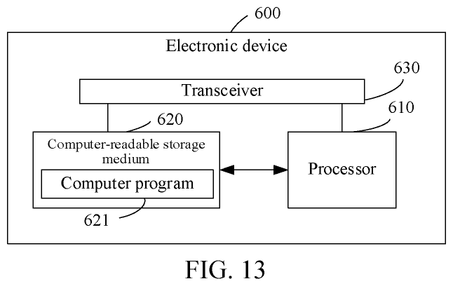

FIG. 13 is a schematic structural diagram of an electronic device 600 according to an embodiment of this disclosure.

As shown in FIG. 13, the electronic device 600 includes at least a processor 610 and a computer-readable storage medium 620. The processor 610 and the computer-readable storage medium 620 may be connected through a bus or in another manner. The computer-readable storage medium 620 is configured to store a computer program 621, the computer program 621 includes computer instructions, and the processor 610 is configured to execute the computer instructions stored in the computer-readable storage medium 620. The processor 610 is a computing core and a control core of the electronic device 600. The processor 610 is suitable for implementing one or more computer instructions, and is suitable for loading and executing one or more computer instructions, to implement corresponding method procedures or corresponding functions.

In an example, the processor 610 may also be referred to as a central processing unit (CPU). The processor 610 may include, but is not limited to, a general-purpose processor, a digital signal processor (DSP), an application-specific integrated circuit (ASIC), a field programmable gate array (FPGA), or another programmable logic device, discrete component gate or transistor logic device, a discrete hardware component, and the like.

In an example, the computer-readable storage medium 620 may be a high-speed RAM memory, or may be a non-volatile memory, for example, at least one magnetic disk memory, or in one embodiment, may further be at least one computer-readable storage medium located away from the processor 610. In some examples, the computer-readable storage medium 620 includes, but is not limited to, a volatile memory and/or a non-volatile memory. The non-volatile memory may be a read-only memory (ROM), a programmable ROM (PROM), an erasable PROM (EPROM), an electrically EPROM (EEPROM), or a flash memory. The volatile memory may be a random access memory (RAM) serving as an external cache. Through illustrative but not limited description, RAMs in many forms are available, for example, a static RAM (SRAM), a dynamic RAM (DRAM), a synchronous DRAM (SDRAM), a double data rate SDRAM (DDRSDRAM), an enhanced SDRAM (ESDRAM), a synch link DRAM (SLDRAM) and a direct rambus RAM (DRRAM).

As shown in FIG. 13, the electronic device 600 may further include a transceiver 630

The processor 610 can control the transceiver 630 to communicate with another device, to transmit information or data to another device, or to receive information or data transmitted by another device. The transceiver 630 may include a transmitter and a receiver. The transceiver 630 may further include an antenna, and there may be one or more antennas.

Components of the electronic device 600 are connected through a bus system, where in addition to a data bus, the bus system further includes a power bus, a control bus, and a status signal bus.

The electronic device 600 may be any electronic device having a data processing capability. The computer-readable storage medium 620 stores a first computer instruction. The processor 610 loads and executes the first computer instruction stored in the computer-readable storage medium 620, to implement corresponding operations in the method 200. In other words, the first computer instruction in the computer-readable storage medium 620 is loaded by the processor 610 to execute corresponding operations. To avoid repetition, details are not described herein again. The computer-readable storage medium 620 stores a second computer instruction. The processor 610 loads and executes the second computer instruction stored in the computer-readable storage medium 620, to implement corresponding operations in the method 300. In other words, the second computer instruction in the computer-readable storage medium 620 is loaded by the processor 610 to execute corresponding operations. To avoid repetition, details are not described herein again.

According to another aspect of this disclosure, an embodiment of this disclosure provides a chip. The chip may be an integrated circuit chip having a signal processing capability, which can implement or perform the methods, the operations, and logical block diagrams that are disclosed in the embodiments of this disclosure. The chip may also be referred to as a system-level chip, a system chip, a chip system, a system on a chip, or the like. The chip can be applied to various electronic devices on which the chip can be mounted, so that the device on which the chip is mounted can perform corresponding operations in the methods or logical block diagrams disclosed in the embodiments of this disclosure. For example, the chip may be suitable for implementing one or more computer instructions, and is suitable for loading and executing one or more computer instructions, to implement corresponding method procedures or corresponding functions.

According to another aspect of this disclosure, an embodiment of this disclosure provides a computer-readable storage medium (Memory). The computer-readable storage medium is a memory device of a computer, and is configured to store programs and data. The computer-readable storage medium herein may include an internal storage medium in the computer, and certainly may also include an extended storage medium supported by the computer. The computer-readable storage medium provides a storage space, and the storage space stores an operating system of an electronic device. The storage space stores computer instructions suitable to be loaded and executed by a processor. The computer instructions are read and executed by the processor of a computer device, so that the computer device executes corresponding operations in the methods or logical block diagrams disclosed in the embodiments of this disclosure.

According to another aspect of this disclosure, an embodiment of this disclosure provides a computer program product or a computer program. The computer program product or the computer program includes a computer instruction, and the computer instruction is stored in a computer-readable storage medium. A processor of a computer device reads the computer instruction from the computer-readable storage medium, and the processor executes the computer instruction, so that the computer device executes corresponding operations in the methods or logical block diagrams disclosed in the embodiments of this disclosure. In other words, when the solutions provided in this disclosure are implemented by using software, all or some of the solutions may be implemented in a form of the computer program product or the computer program. The computer program product or the computer program includes one or more computer instructions. When the computer program instructions are loaded and executed on a computer, all or some of procedures of the embodiments of this disclosure are run or all or some of functions of the embodiments of this disclosure are implemented.

The computer involved in this disclosure may be a general-purpose computer, a dedicated computer, a computer network, or another programmable apparatus. The computer instructions involved in this disclosure may be stored in a computer-readable storage medium or may be transmitted from one computer-readable storage medium to another computer-readable storage medium. For example, the computer instructions may be transmitted from one website, computer, server or data center to another website, computer, server or data center in a wired (for example, a coaxial cable, an optical fiber or a digital subscriber line (DSL)) or wireless (for example, infrared, wireless or microwave) manner.

It is noted that the units and procedure steps described with reference to the embodiments disclosed in this specification can be implemented in electronic hardware or a combination of computer software and electronic hardware. Whether these functions are executed in a manner of hardware or software depends on specific applications and design constraints of the technical solutions. In other words, different methods can be used to implement the described functions for each particular application, but the implementation by the different methods are considered within the protection scope of this disclosure.

One or more modules, submodules, and/or units of the apparatus can be implemented by processing circuitry, software, or a combination thereof, for example. The term module (and other similar terms such as unit, submodule, etc.) in this disclosure may refer to a software module, a hardware module, or a combination thereof. A software module (e.g., computer program) may be developed using a computer programming language and stored in memory or non-transitory computer-readable medium. The software module stored in the memory or medium is executable by a processor to thereby cause the processor to perform the operations of the module. A hardware module may be implemented using processing circuitry, including at least one processor and/or memory. Each hardware module can be implemented using one or more processors (or processors and memory). Likewise, a processor (or processors and memory) can be used to implement one or more hardware modules. Moreover, each module can be part of an overall module that includes the functionalities of the module. Modules can be combined, integrated, separated, and/or duplicated to support various applications. Also, a function being performed at a particular module can be performed at one or more other modules and/or by one or more other devices instead of or in addition to the function performed at the particular module. Further, modules can be implemented across multiple devices and/or other components local or remote to one another. Additionally, modules can be moved from one device and added to another device, and/or can be included in both devices.

The use of “at least one of” or “one of” in the disclosure is intended to include any one or a combination of the recited elements. For example, references to at least one of A, B, or C; at least one of A, B, and C; at least one of A, B, and/or C; and at least one of A to C are intended to include only A, only B, only C or any combination thereof. References to one of A or B and one of A and B are intended to include A or B or (A and B). The use of “one of” does not preclude any combination of the recited elements when applicable, such as when the elements are not mutually exclusive

The foregoing disclosure includes some embodiments of this disclosure which are not intended to limit the scope of this disclosure. Other embodiments shall also fall within the scope of this disclosure.

What is claimed is:

1. A method of haptic signal interpolation, the method comprising:
receiving a bit stream including coded information of a haptic signal, the haptic signal including a plurality of haptic events;
determining an interpolation type of a first haptic event component in a first haptic event of the plurality of haptic events according to at least an identifier in the coded information of the haptic signal;
performing a signal value interpolation between a first signal value of the first haptic event component and a second signal value of a second haptic event component in the first haptic event based on the interpolation type of the first haptic event component, the second haptic event component preceding or following the first haptic event component; and
reconstructing the haptic signal based on at least the signal value interpolation.

2. The method according to claim 1, wherein the determining the interpolation type comprises:
acquiring a first identifier from the coded information, the first identifier indicating the interpolation type; and
determining the interpolation type of the first haptic event component based on the first identifier.

3. The method according to claim 2, wherein the acquiring the first identifier comprises:
acquiring, based on the coded information, a second identifier indicating whether the first identifier exists; and
acquiring the first identifier when the second identifier indicates that the first identifier exists.

4. The method according to claim 2, wherein the acquiring the first identifier comprises:
acquiring a third identifier based on the coded information, the third identifier indicating whether the first haptic event is a continuous event; and
acquiring the first identifier from the coded information when the third identifier indicates that the first haptic event is the continuous event.

5. The method according to claim 2, wherein:
the acquiring the first identifier comprises:
acquiring a data structure of the first haptic event from the coded information, the data structure of the first haptic event comprising the first identifier; and
the determining the interpolation type comprises:
determining the interpolation type that is indicated by the first identifier, the interpolation type being applied to a plurality of haptic event components comprising the first haptic event component.

6. The method according to claim 2, wherein:
the acquiring the first identifier comprises:
acquiring a data structure of the first haptic event component from the coded information, the data structure of the first haptic event component comprising the first identifier; and
the determining the interpolation type comprises:
determining the interpolation type of the first haptic event component according to the first identifier.

7. The method according to claim 2, wherein the method further comprises:
applying the interpolation type to one or more haptic event components of the first haptic event following the first haptic event component until a data structure in the first haptic event comprises a different first identifier or until a last haptic event component in the first haptic event.

8. The method according to claim 1, wherein the performing the signal value interpolation comprises:
performing an interpolation between the first signal value of the first haptic event component and the second signal value of the second haptic event component based on the first signal value of the first haptic event component and the interpolation type of the first haptic event component.

9. The method according to claim 1, wherein the interpolation type of the first haptic event component comprises at least one of: nearest neighbor interpolation, linear interpolation, cubic spline interpolation, Akima interpolation, Bezier interpolation, B-spline interpolation, Lagrange interpolation, Newton interpolation, and custom algorithm interpolation.

10. The method according to claim 1, wherein the bit stream is obtained by decapsulating at least one of a haptic media file, a haptic media segment, or a haptic media track.

11. A method of haptic signal interpolation, the method comprising:
acquiring a haptic signal;
determining a first interpolation type based on the haptic signal; and
encoding the haptic signal into coded information in a bit stream of the haptic signal based on the first interpolation type, the first interpolation type being associated with a signal value interpolation between a first signal value of a first haptic event component and a second signal value of a second haptic event component in a first haptic event, and the second haptic event component preceding or following the first haptic event component.

12. The method according to claim 11, wherein the encoding comprises:
encoding a first identifier into the bit stream of the haptic signal, the first identifier indicating the first interpolation type.

13. The method according to claim 12, wherein the method further comprises:
encoding a second identifier or a third identifier into the coded information, the second identifier indicating whether the first identifier exists, and the third identifier indicating whether the first haptic event is a continuous event.

14. The method according to claim 12, wherein the encoding the first identifier comprises:
encoding a data structure of the first haptic event and a data structure of the first haptic event component into the coded information, and
the data structure of the first haptic event comprising the first identifier, or the data structure of the first haptic event component comprising the first identifier.

15. The method according to claim 11, wherein the method further comprises:
encapsulating the bit stream, to obtain a haptic media file of the haptic signal; and
transmitting the haptic media file, a haptic media file segment in the haptic media file, or a haptic media track in the haptic media file.

16. The method according to claim 11, wherein the first interpolation type comprises at least one of: nearest neighbor interpolation, linear interpolation, cubic spline interpolation, Akima interpolation, Bezier interpolation, B-spline interpolation, Lagrange interpolation, Newton interpolation, and custom algorithm interpolation.

17. An apparatus for haptic signal interpolation, comprising processing circuitry configured to:
receive a bit stream including coded information of a haptic signal, the haptic signal including a plurality of haptic events;
determine an interpolation type of a first haptic event component in a first haptic event of the plurality of haptic events according to at least an identifier in the coded information of the haptic signal;
perform a signal value interpolation between a first signal value of the first haptic event component and a second signal value of a second haptic event component in the first haptic event based on the interpolation type of the first haptic event component, the second haptic event component preceding or following the first haptic event component; and
reconstruct the haptic signal based on at least the signal value interpolation.

18. The apparatus according to claim 17, wherein the processing circuitry is configured to:
acquire a first identifier from the coded information, the first identifier indicating the interpolation type; and
determine the interpolation type of the first haptic event component based on the first identifier.

19. The apparatus according to claim 18, wherein the processing circuitry is configured to:
acquire, based on the coded information, a second identifier indicating whether the first identifier exists; and
acquire the first identifier when the second identifier indicates that the first identifier exists.

20. The apparatus according to claim 18, wherein the processing circuitry is configured to:
acquire a third identifier based on the coded information, the third identifier indicating whether the first haptic event is a continuous event; and
acquire the first identifier from the coded information when the third identifier indicates that the first haptic event is the continuous event.
